(19) United States
(12) Patent Application Publication
(10) Pub. No.: US 2019/0156213 A1
(43) Pub. Date: May 23, 2019

(54) GRADIENT COMPRESSING APPARATUS, GRADIENT COMPRESSING METHOD, AND NON-TRANSITORY COMPUTER READABLE MEDIUM

(71) Applicant: Preferred Networks, Inc., Tokyo (JP)

(72) Inventors: Yusuke Tsuzuku, Tokyo (JP); Hiroto Imachi, Tokyo (JP); Takuya Akiba, Tokyo (JP)

(21) Appl. No.: 16/171,340

(22) Filed: Oct. 25, 2018

(30) Foreign Application Priority Data
Oct. 26, 2017 (JP) 2017-207200

(51) Int. Cl. G06N 3/08; G06F 17/18; G06N 3/04; H03M 7/30; H04L 12/24

(52) U.S. Cl. CPC G06N 3/084; G06F 17/18; H04L 41/142; H03M 7/30; G06N 3/04

(57) ABSTRACT

According to one embodiment, a gradient compressing apparatus includes a memory and processing circuitry. The memory stores data. The processing circuitry is configured to calculate statistics of gradients calculated regarding a plurality of parameters being learning targets, with respect to an error function in learning; determine, based on the statistics, whether or not to be a transmission parameter being a parameter which transmits gradients regarding each of the parameters, via a communication network; and quantize a gradient representative value being a representative value of gradients regarding the parameter determined to be a transmission parameter.

### CROSS-REFERENCE TO RELATED APPLICATIONS

This application is based upon and claims the benefit of priority from Japanese Patent Application No. 2017-207200, filed on Oct. 26, 2017, the entire contents of which are incorporated herein by reference.

### FIELD

Embodiments described herein relate to a gradient compressing apparatus, gradient compressing method, and a non-transitory computer readable medium.

### BACKGROUND

In handling big data, distributing it by using a cluster, a cloud, or the like and performing processing have been put widely into practice. Also in performing deep learning, due to the depth of the layer of a model together with the size of data, the learning often has been distributed and performed. Nowadays, due to a large amount of data to be handled, and further, a need of communication for an improvement in computing power and also an improvement in computing power in parallel computation, when distributed deep learning is performed, a communication time greatly increases as compared with an operation time, and a learning speed is often rate-limited by data communication. The communication can also be sped up by using a wide-band communication medium such as InfiniBand, but there is a problem that costs become high.

In the distributed deep learning, communication is performed in order to calculate a mean, in all nodes, of gradients operated mainly in the respective nodes. As a technique of transmitting the gradients, a technique of compressing by transmitting only one bit per each parameter, a technique of compressing by transmitting only a parameter having a value of a gradient larger than a threshold, a technique of compressing at random, and the like have been studied. However, any technique has difficulty of achieving both high accuracy and a low compression ratio or requiring subtle control of hyperparameters.

### BRIEF DESCRIPTION OF THE DRAWINGS

FIG. 1 is a diagram illustrating an outline of a learning system according to one embodiment.

FIG. 2 is a block diagram illustrating a function of a distributed learning apparatus according to one embodiment.

FIG. 3 is a chart illustrating processing of gradient compression in the distributed learning apparatus according to one embodiment.

FIG. 4 is a chart illustrating processing of data quantization in the distributed learning apparatus according to one embodiment.

FIG. 5A to FIG. 5C are charts illustrating learning results by the learning system according to one embodiment.

FIG. 6A to FIG. 6C are charts illustrating results of data compression by the learning system according to one embodiment.

### DETAILED DESCRIPTION

According to one embodiment, a gradient compressing apparatus includes a memory and processing circuitry. The memory stores data. The processing circuitry is configured to calculate statistics of gradients calculated regarding a plurality of parameters being learning targets, with respect to an error function in learning; determine, based on the statistics, whether or not to be a transmission parameter being a parameter which transmits gradients regarding each of the parameters, via a communication network; and quantize a gradient representative value being a representative value of gradients regarding the parameter determined to be a transmission parameter.

First, terms to be used in this embodiment will be explained.

“Parameter” indicates an internal parameter of a neural network.

“Hyperparameter” indicates a parameter in the exterior of the neural network with respect to the parameter. For example, it means various thresholds set in advance, and the like. In this embodiment, for example, in the following explanation, a reference variance scale factor (predetermined scale factor) α, an attenuation factor γ, and a quantifying bit number k are hyperparameters. Other than the above, in this embodiment, although other hyperparameters such as a batch size and the number of epochs also exist, no explanation is made in detail.

“Accuracy” indicates recognition accuracy of the neural network. Unless otherwise stated, it indicates accuracy evaluated by using a data set other than a data set used for learning.

“Gradient” indicates a value obtained by calculating a partial differential of an error function with respect to each parameter of the neural network at a data point. It is calculated by a back propagation method and used for optimization of the parameter.

“Optimization of parameter” indicates a procedure which reduces a value of the error function by adjusting the parameter. A SGD (Stochastic Gradient Descent) using gradients is a general method, and the SGD is used also in this embodiment.

“Compression ratio” is a value indicating (the total of the number of transmitted parameters in all nodes)/((the total number of parameters)×(the number of nodes)). It is meant that the lower a compression ratio is, the better performance in compression is.

Hereinafter, a gradient compressing apparatus according to this embodiment will be explained by using the drawings.

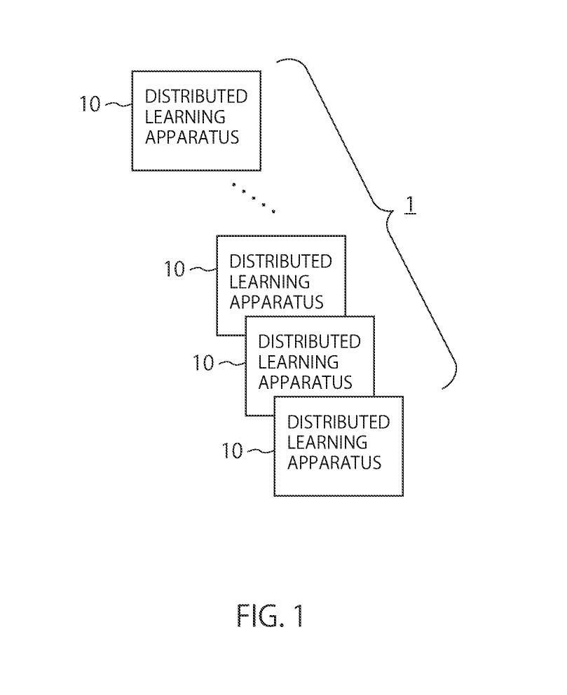

FIG. 1 is a diagram illustrating a learning system 1 according to this embodiment. The learning system 1 includes a plurality of distributed learning apparatuses 10. The respective distributed learning apparatuses are connected via a communication network. In a connection method, the respective distributed learning apparatuses may be mutually connected with one another, by preparing a hub, the respective distributed learning apparatuses may be connected via the hub, or the respective distributed learning apparatuses may be connected on a ring-shaped communication network.

The communication network need not necessarily be a high-speed one. For example, it may be formed by a typical LAN (Local Area Network). Further, a communication technique or a communication method thereof is not particularly limited.

In the respective distributed learning apparatuses 10, for example, deep learning is performed, and various parameters are calculated. The calculated parameters may be shared in the respective distributed learning apparatuses 10, to update an averaged one as a parameter for the next learning. Such a distribution makes it possible to execute the deep learning having a large amount of data in a parallel manner. The distributed learning apparatus 10 may be configured by including, for example, a GPU (Graphics Processing Unit), and in this case, the learning system 1 is configured to include a GPU cluster.

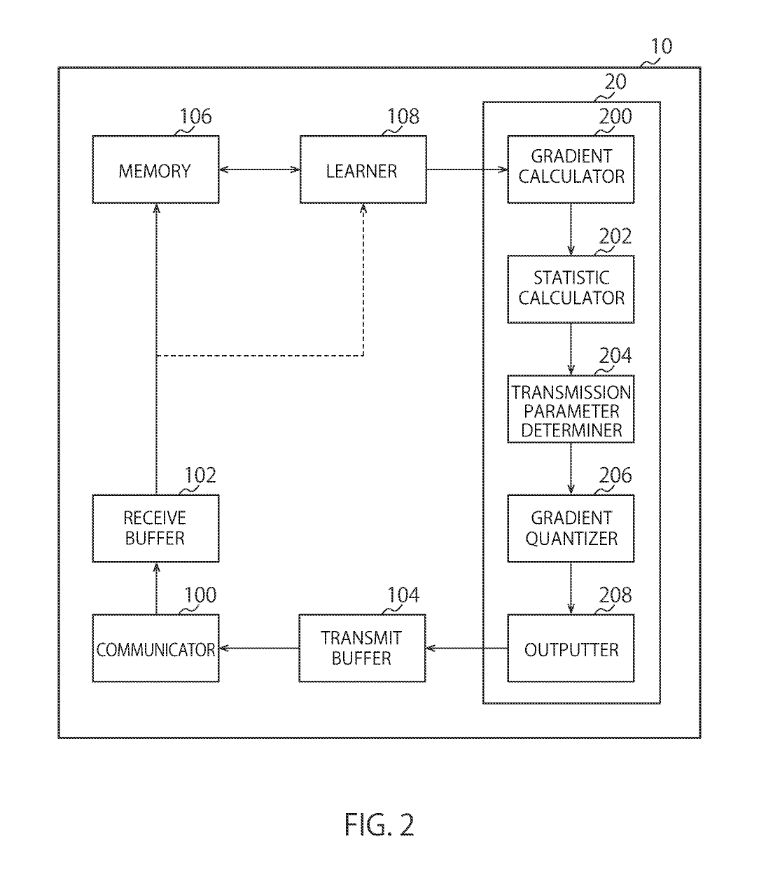

FIG. 2 is a block diagram illustrating a function of the distributed learning apparatus 10. The distributed learning apparatus 10 includes a communicator 100, a receive buffer 102, a transmit buffer 104, a memory 106, a learner 108, and a gradient compressing apparatus 20.

The communicator 100 connects the above-described communication network and the interior of the distributed learning apparatus 10. It is sufficient that an interface of this communicator 100 appropriately corresponds to the communication technique or the communication method of the communication network. When the communicator 100 receives data, it stores the data into the receive buffer 102 and transmits data stored in the transmit buffer 104 to the exterior thereof. For example, all or a plurality of the distributed learning apparatuses 10 are synchronized with one another at timing of communication. Such synchronization with one another makes it possible to share values of gradients in all or a plurality of the distributed learning apparatuses 10 and perform learning in the next step.

The memory 106 stores data necessary for processing in the distributed learning apparatus 10. For example, it is configured to include memory, and data necessary for learning is stored therein. This data is what is called supervised data, information of parameters already obtained by learning, or the like. The data stored in the receive buffer 102 may be transferred to the memory 106, to store the received data.

The learner 108 is a part which performs machine learning based on the data stored in the memory 106, and for example, by executing such learning operation by a neural network as deep learning, the respective parameters being targets of learning are calculated. A program for operating this learner 108 may be stored in the memory 106. Further, as another example, as drawn with a broken line, the learner 108 may directly refer to the data stored in the receive buffer 102, to perform learning.

Hereinafter, the number of learning parameters is set as n, and the ith (“0” (zero)≤i<n) parameter is represented as wᵢ. Further, an error function to be used for evaluation in the learner 108 is set as E.

Note that in principle, in one distributed learning apparatus 10, learning is performed by mini batches, but a case where learning is performed by batch learning using gradients, or the like can also be applied thereto. Mini-batch learning is a technique of updating a parameter for each mini batch in which training data is divided for each certain degree of size.

When learning is performed by mini batches, the learner 108 in the distributed learning apparatus 10 calculates gradients of a parameter wᵢ corresponding to each of the mini batches assigned to the distributed learning apparatus 10. The total sum of the calculated gradients for each mini batch is shared at all nodes, and by the stochastic gradient descent by using these shared gradients, the optimization in the next step of the parameter wᵢ is performed.

The gradient compressing apparatus 20 includes a gradient calculator 200, a statistic calculator 202, a transmission parameter determiner 204, a gradient quantizer 206, and an outputter 208. This gradient compressing apparatus 20 quantizes gradients of the respective parameters being learning targets of the machine learning and compresses a data amount thereof.

The gradient calculator 200 calculates gradients of the respective parameters from a set of the respective parameters outputted from the learner 108. The calculation of gradients in this gradient calculator 200 is similar to a calculation method of gradients in a general back propagation method. For example, when a partial differential based on the parameter wᵢ is put as ∇ᵢ, a gradient regarding the parameter wᵢ can be mentioned as ∇ᵢE. This gradient is found by the back propagation method, for example, by propagating it through a network in order from an input layer, storing an output of a layer regarding the parameter wᵢ, and based on an output value obtained from an output layer next, back-propagating an error (or a partial differential value of an error) to the layer of the parameter wᵢ. The gradient calculator 200 stores the calculated values of the gradients with respect to the respective parameters into a non-illustrated buffer.

Note that the gradients may be calculated during learning. In this case, in the gradient compressing apparatus 20, a function of calculating gradients need not be included, but the learner 108 may include a function of the gradient calculator 200. That is, the gradient calculator 200 is not an essential element in the gradient compressing apparatus 20. Then, the statistic calculator 202 to be explained next may calculate statistics based on the gradients of the respective parameters calculated by the learner 108.

The statistic calculator 202 calculates statistics regarding the gradients with respect to the respective parameters calculated by the gradient calculator 200. As the statistics, for example, a mean value and a variance value can be used. The statistic calculator 202 calculates, from the gradients for each parameter wᵢ calculated from a data set in a mini batch, a mean value and a variance value of the gradients in the mini batch.

The transmission parameter determiner 204 determines whether or not to transmit the gradients regarding the parameter wᵢ based on the found statistics, here, a mean value and a variance value vᵢ. Here, a parameter which transmits the gradients is indicated as a transmission parameter.

The gradient quantizer 206 executes quantization of a representative value of the gradients regarding a parameter wᵢ determined as the transmission parameter. The representative value of the gradients is a value of gradients to be reflected to the parameter wᵢ to be used for learning in the next step, and for example, a mean value of the gradients found as described above is used, but a mode value, a median value, or the like may be used.

A representative value of gradients with respect to a parameter wᵢ is indicated as a gradient representative value xᵢ. That is, an array x is an array having n-piece elements, and the gradient representative value xᵢ being an element thereof corresponds to a parameter wᵢ (transmission parameter) which performs quantization in parameters wᵢ. With respect to a gradient representative value xᵢ corresponding to a parameter wᵢ being no transmission parameter, for example, by setting a flag in which all bits are “0” (zero), a notification not to be transmitted may be made, or by separately preparing an array regarding an index of a transmission parameter, determination of whether or not to be a transmission parameter may be made based on the array. Then, the gradient quantizer 206 quantizes the elements of the array x subjected to scaling by a maximum value of the array x, based on a quantifying bit number k, and quantizes them by imparting necessary data.

The outputter 208 outputs the data quantized by the gradient quantizer 206 to the transmit buffer 104 and shares gradient values of parameters with the other distributed learning apparatuses 10.

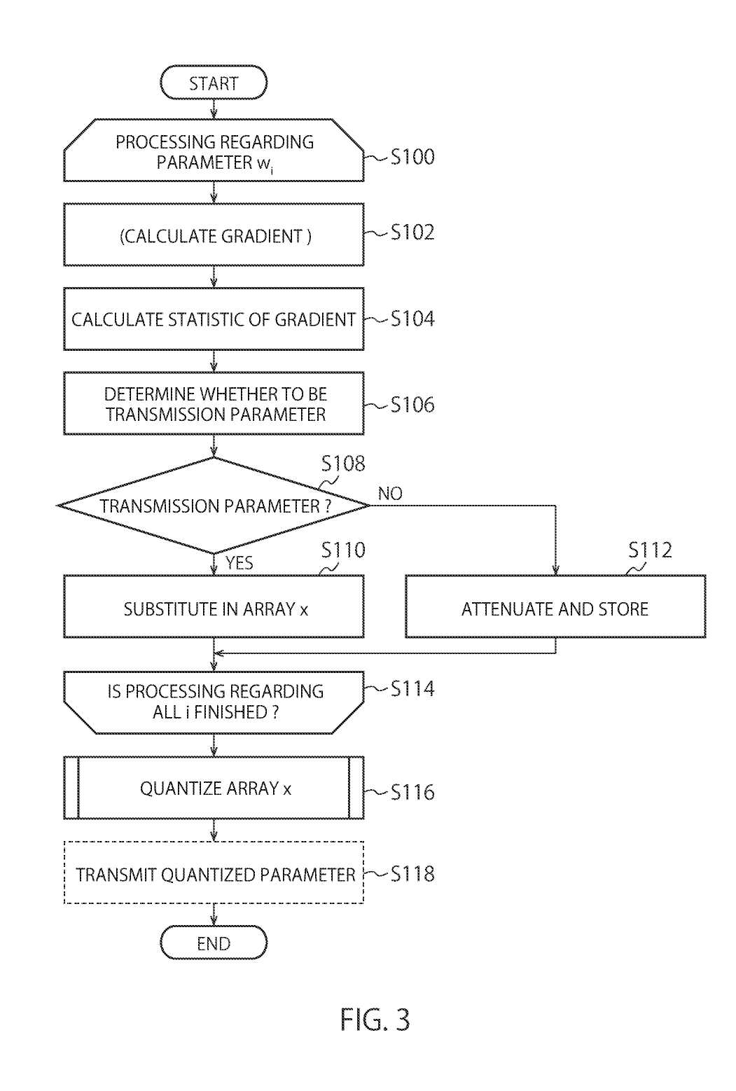

FIG. 3 is a flowchart illustrating a flow of processing from calculating gradients by learning in a step to sharing the gradients into the next step.

First, processing is performed regarding a parameter wᵢ (S100).

The gradient calculator 200 calculates a gradient of an error function regarding the parameter wᵢ by the back propagation method (S102). Note that processing until the gradient is found may be performed by the learner 108 as described above. When the gradient is calculated by the learner 108, the processing in S102 is not included in a loop of S100, but the processing may be performed from after finding gradients regarding all parameters. In this case, as described above, the gradient calculator 200 is included in the learner 108 and is not an essential configuration element in the gradient compressing apparatus 20.

Next, the statistic calculator 202 calculates statistics of the gradients of the parameter wᵢ (S104). As the statistics, for example, a mean value μᵢ and a variance value vᵢ are calculated.

In a case where the number of samples of a data set in a mini batch is set as m, when a value of an error function in a case of using the jth data is set as Eⱼ, the mean value μᵢ can be expressed as follows.

$${μ}_{i} = \frac{1}{m} {\sum }_{j = 0}^{m - 1} {∇}_{i} {E}_{j} \qquad ( 1 )$$

Similarly, the variance value vᵢ can be expressed as follows.

$${v}_{i} = \frac{1}{m} {\sum }_{j = 0}^{m - 1} {( {∇}_{i} {E}_{j} - {μ}_{i} )}^{2} = \frac{1}{m} {\sum }_{j = 0}^{m - 1} {( {∇}_{i} {E}_{j} )}^{2} - {μ}_{i}^{2} \qquad ( 2 )$$

Note that in the following explanation, the statistics to be used are explained as the mean value and the variance value, but without being limited to these, and for example, in place of the mean value, another statistic such as a mode or a median can be used. In this case, a pseudo variance value using the statistic such as the mode or the median in place of the mean value may be used as a substitute for the variance value. That is, a value substituting the mode or the median for μᵢ in eq. 2 may be used. Thus, any statistic that has a relationship similar to that of a mean and a variance is allowed to use. Further, in the above, a sample variance is used, but an unbiased variance may also be used.

In finding these mean value and variance value, non-illustrated first buffer and second buffer prepared for each parameter wᵢ may be used. The first buffer is a buffer which stores the sum of gradients regarding the parameter wᵢ, and the second buffer is a buffer which stores the sum of squares of the gradients. These buffers are initialized at “0” (zero) at timing when learning is started, namely, start timing of a first step.

The statistic calculator 202 adds the sum of the gradients to the first buffer and adds the sum of the squares of the gradients to the second buffer. Then, the statistic calculator 202 finds a mean value by dividing the value stored in the first buffer by the number of samples m. Similarly, by dividing the value stored in the second buffer by the number of samples m and subtracting a square of the mean value found from the stored value in the first buffer, a variance value is calculated. When the mean value of gradients is not used, a statistic corresponding thereto may be stored in the first buffer.

Note that as expressed in the below-described eq. 4, when a mean value and a variance value are compared, they can be rewritten into a comparison of a mean value of samples themselves and a mean value of squares of the samples. Thus, comparing the mean value of the samples and the mean value of the squares of the samples allows a transmission parameter to be determined without finding the variance value from the value stored in the second buffer.

When the buffers are not initialized in a previous step, such a manner as described above allows a state until the previous step to be reflected to a determination of whether or not to transmit gradients regarding a parameter wᵢ.

Next, the transmission parameter determiner 204 determines whether or not a parameter wᵢ is a transition parameter based on the statistics calculated by the statistic calculator 202 (S106). The transmission parameter determiner 204 determines that a parameter regarding the gradients is a transmission parameter, for example, when the following expression is satisfied by using a reference variance scale factor α′.

$${μ}_{i}^{2} > \frac{{α}^{′}}{m} {v}_{i} \qquad ( 3 )$$

When the weak law of large numbers is used, by dividing by m as in eq. 3, a conversion from a variance of one sample to a variance of a mean of gradients in a mini batch is indicated. By rewriting the variance value vᵢ by (a mean value of squares of gradients)−(a square of a mean value of gradients), this expression is rewritten into the following expression by using a reference variance scale factor α (≠α′).

$${μ}_{i}^{2} > α ( {\sum }_{j = 0}^{m - 1} {( \frac{{∇}_{i} {E}_{j}}{m} )}^{2} ) \qquad ( 4 )$$

That is, by such a deformation as described above, based on a comparison of a mean value and a mean value of squares of gradients, being equal to a comparison with a variance value is found. The reference variance scale factor α is, for example, 1.0. Without being limited to this, 0.8, 1.5, 2.0, or another value is also applicable. This reference variance scale factor α is a hyperparameter, and for example, may be changed depending on a learning method, learning contents, a learning target, and so on.

In particular, in place of the variance value in eq. 2, the following expression is used as an unbiased variance, thereby being α=1 in a case of α′=1 in eq. 2 and eq. 4.

$${v}_{i} = \frac{1}{m - 1} {\sum }_{j = 0}^{m - 1} {( {∇}_{i} {E}_{j} - {μ}_{i} )}^{2} \qquad ( 5 )$$

These eq. 3, eq. 4, and the following expressions are values to be determined in a mini batch and comparisons by a value independent of the number of nodes n and m×n being the overall batch size.

An expression to be used as a determination expression is not limited to eq. 3 and eq. 4, but each of the determination expressions as mentioned below may be used.

μᵢ²>β∥∇ᵢE∥ₚ^{q} (6)

∥∇ᵢE∥ₚ^{q}>β∥∇ᵢE∥_{p′}^{q′} (7)

Here, p, p′, q, q′, and β are scalar values to be given as hyperparameters, and ∥⋅∥ₚ expresses a pth-order norm (Lₚ norm). Other than them, an expression similar to these may be used as a determination expression.

When the parameter wᵢ is determined to be a transmission parameter (S108: Yes), the parameter wᵢ is added to an array x (S110). Note that this array x is a convenient one, and in practice, by outputting an index i of the parameter being the transmission parameter to the gradient quantizer 206 and referring to the parameter wᵢ based on the index i, processing subsequent to the following quantization may be performed. Further, at this timing, the first buffer and the second buffer are initialized at “0” (zero).

On the other hand, when the parameter wᵢ is determined not to be a transmission parameter (S108: No), the parameter wᵢ is not added to the array x, and furthermore, the mean value and the variance value of the gradients calculated by the statistic calculator 202 are attenuated based on the attenuation factor γ being a hyperparameter and stored into the first buffer and the second buffer (S112). More specifically, γ×(the mean value of the gradients) is stored into the first buffer and γ²×(the variance value of the gradients) is stored into the second buffer.

The attenuation factor γ is a value indicating an index of to what extent the present state affects the future, and for example, is a value such as 0.999. Without being limited to this value, it may be another value being 1 or less, for example, the other value such as 0.99 or 0.95. In general, it is set to a value close to 1, but for example, as long as the present state is not intended to be used in the future, it may be set to γ=“0” (zero). Thus, γ may take an arbitrary value of [0, 1].

Further, an attenuation factor regarding a mean value and a mean value of squares need not be the same value, but may be set to different values. For example, an attenuation factor regarding the first buffer may be set to an attenuation factor of γ₁=1.000, and an attenuation factor regarding the second buffer may be set to an attenuation factor of γ₂=0.999.

Next, regarding all the indices i, by determining whether or not to be transmission parameters, loop processing is finished (S114). When the processing regarding all the indices i is not performed, the processing from S102 to S112 is performed with respect to the next index.

Note that the loop processing from S100 to S114 may be subjected to a parallel operation as long as the distributed learning apparatus 10 is capable of performing the parallel operation.

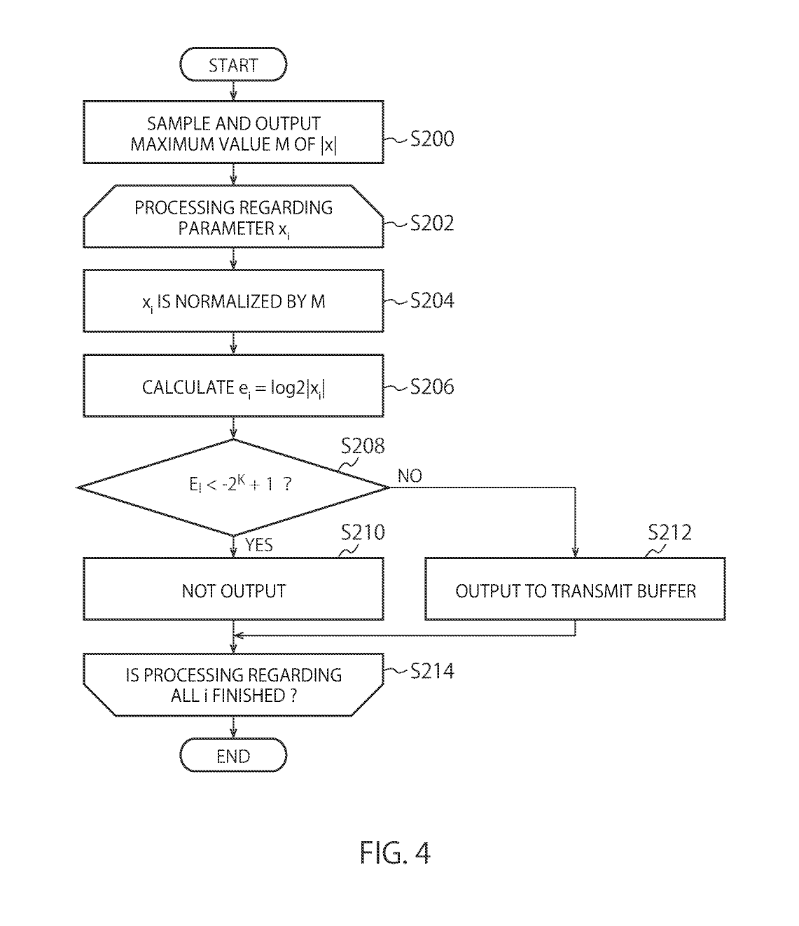

Next, the gradient quantizer 206 performs quantization regarding data of the transmission parameter (S116). FIG. 4 is a flowchart illustrating processing of operation of the quantization of the data of the transmission parameter. This operation illustrated in FIG. 4 is executed by the gradient quantizer 206. To the gradient quantizer 206, the array x configured by gradients regarding a transmission parameter wᵢ and the quantifying bit number k being a hyperparameter are inputted.

In the quantization step, first, from the array x, a maximum value M of absolute values of elements thereof is sampled, and the maximum value M is outputted to the transmit buffer 104 (S200). Specifically, a value of M in the following mathematical expression is found and outputted to the transmit buffer 104.

$$M = {max}_{i} ( \vert {x}_{i} \vert ) \qquad ( 8 )$$

As a sampling method of the maximum value M, a general method is used. At this timing, in the transmit buffer 104, the value of the maximum value M is stored.

Next, processing of each gradient representative value xᵢ is executed (S202). First, each gradient representative value xᵢ is normalized by the maximum value M (S204). That is, the gradient representative value xᵢ is converted based on an expression of xᵢ=xᵢ/M. Note that as long as the distributed learning apparatus 10 deals with a SIMD (Single Instruction Multiple Data) operation or the like, this processing may be performed by the SIMD operation or the like before entering a loop.

Since the maximum value of the array x before the normalization is M, all of absolute values of the elements of the array x after the normalization are 1 or less. That is, setting 2 as a radix and setting a mantissa to [−1, 1] make it possible to rewrite into a form of (mantissa)×2^{-(positive exponent)}. The gradient quantizer 206 omits information of the mantissa and approximates and compresses the mean value of the gradients by the maximum value M and information of the exponent part.

Next, the exponent part of the normalized gradient representative value xᵢ which has the radix of 2 is sampled (S206). The sampling of the exponent part is performed by finding a logarithmic value of an absolute value of the normalized gradient representative value xᵢ as in the below-indicated expression.

eᵢ=log₂(|xᵢ|) (9)

Next, regarding the respective parameters, a determination of whether or not eᵢ in eq. 9 is equal to or more than a minimum value which can be indicated by the quantifying bit number k is made (S208). This determination is executed by the following expression.

eᵢ<−2^{k}+1 (10)

Based on this determination result, it is determined whether or not to output the gradients. This determination is different from the determination executed by the transmission parameter determiner 204, and for example, when the mean value of the gradients is below the minimum value which can be indicated by the quantifying bit number k, this determination is made as “0” (zero) and “0” (zero) can be expressed by not transmitting, and therefore, it is executed. For example, in a case of k=3, it becomes possible to indicate eight-stage values based on an exponentiation of 2 (to 2 raised to the power of 2³=8) to 2⁸⁻¹ from the maximum value M to M/127. Then, numeric values less than M/127 are regarded as “0” (zero). The quantization is not limited to k=3, but for example, it may be set to k=4 or the like. The larger k is, the more the numeric value to be able to be indicated increases.

When eq. 10 is satisfied (S208: Yes), eᵢ is below the minimum value which can be indicated by using the quantifying bit number k and the maximum value M, and therefore, it is regarded as “0” (zero), and a gradient representative value regarding a parameter wᵢ corresponding to the gradient representative value xᵢ is not outputted to the transmit buffer 104 (S210). That is, by performing the determination, it is determined to which index i a corresponding gradient representative value is not transmitted, and the gradient representative value of the index i is set to “0” (zero), resulting in not transmitting it. By not transmitting it, a receiving side regards the gradient representative value as “0” (zero), to update the parameter, and learning in the next step is performed.

On the other hand, when eq. 10 is not satisfied (S208: No), eᵢ can be approximated and compressed by using the quantifying bit number k and the maximum value M, and therefore, the normalized gradient representative value xᵢ is outputted to the transmit buffer 104 (S212). Here, the value to be outputted is 1+k+ceil (log₂ n) bits, of a sign (1 bit) of the gradient representative value xᵢ with respect to the parameter wᵢ, −floor (eᵢ) (k bit), and an index i (i≤n, thereby being ceil (log₂ n) bit).

Then a determination of whether or not the processing regarding all the indices i is finished is made (S214), and when the processing regarding all the indices i is finished, the processing of gradient compression is finished. When there is an index i not subjected to the processing yet, the processing from S202 is performed with respect to the next index.

When this processing of gradient compression is performed, in the transmit buffer 104, data being the maximum value M of the gradient representative value, for example, of 32 bits (in a case of single precision) and data of the above-described 1+k+ceil (log₂ n) bits regarding each transmission parameter wᵢ are stored.

Note that after completing an output of data regarding all the indices, the array x may be initialized with “0” (zero), or at timing when the learner 108 performs learning, before starting the compression processing of the gradient representative value, the array x may be initialized with “0” (zero).

Back to FIG. 3, next, the communicator 100 transmits the contents compressed by the quantization and stored in the transmit buffer 104 to the other distributed learning apparatuses 10, and at the same time, receives data stored in transmit buffers of the other distributed learning apparatuses 10, and stores it into the receive buffer 102 (S118). At this timing, the first buffer and the second buffer regarding the transmission parameter may be initialized with “0” (zero).

This transmission/reception of data by using the communicator 100 is performed by, for example, processing of Allgathery ( ) in MPI (Message Passing Interface) instructions. As performed by this instruction, for example, values stored in the transmit buffers 104 of the respective distributed learning apparatuses 10 are collected and the collected data is stored into the receive buffers 102 of the respective distributed learning apparatuses 10.

Regarding the data stored in the receive buffers 102, the learners 108 each expand the gradient representative value by performing an operation reverse to the above-described one and perform learning in the next step.

The expansion of the received data is executed by performing processing reverse to the above-described processing. First, the maximum value M of the received gradient representative value is acquired. Then, it is judged, from the index i in the received data, with respect to which parameter the following data is a gradient representative value. Next, in the received data, data corresponding to the exponent part eᵢ is sampled, M×2^{-ei} is calculated, a sign is read from data stored in a sign bit, and a sign of the parameter wᵢ is given.

After expanding parameters as mentioned above regarding data from all the distributed learning apparatuses 10, the learners 108 each execute learning by a learning technique of Momentum SGD, SGD, Adam, or the like.

Note that in a plurality of distributed learning apparatuses 10, when a gradient representative value of a parameter of the same index i is acquired, by calculating the sum of a plurality of the acquired values, learning in the next step may be performed.

The above-described gradient compression need not be performed at every step, but for example, after learning steps collected in some extent in the respective distributed learning apparatuses 10, based on the outputted gradients, by performing the gradient compression and performing the transmission, learning may be put forward.

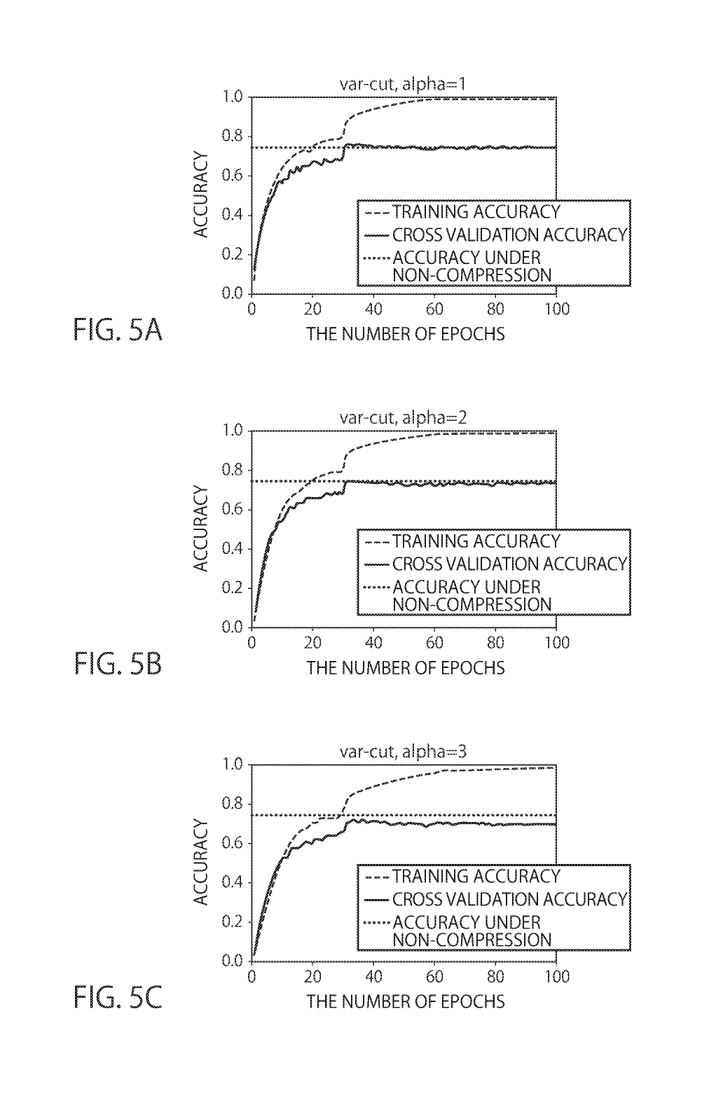

FIG. 5A to FIG. 5C are graphs illustrating states of learning in which the gradient compression according to this embodiment has been performed. In these charts, dotted lines are each a maximum value of accuracy of learning when no gradient compression is performed, broken lines are each a value of an evaluation function when the gradient compression according to this embodiment has been performed, and solid lines are each a curve illustrating the accuracy of learning when the gradient compression according to this embodiment has been performed. That is, the solid lines are each the curve illustrating accuracy of a result of cross validation. Vertical axes each represent the accuracy of learning and horizontal axes each represent the number of steps.

FIG. 5A is a chart illustrating a result in a case of setting the reference variance scale factor to α=1. In this case, it is found that the accuracy equal to that in the case where no gradient compression has been performed is obtained.

FIG. 5B illustrates a case of setting the reference variance scale factor to α=2 and FIG. 5C illustrates a case of setting the reference variance scale factor to α=3, and it is found that although each of them has accuracy lower than that in the result in FIG. 5A, learning having good accuracy is performed.

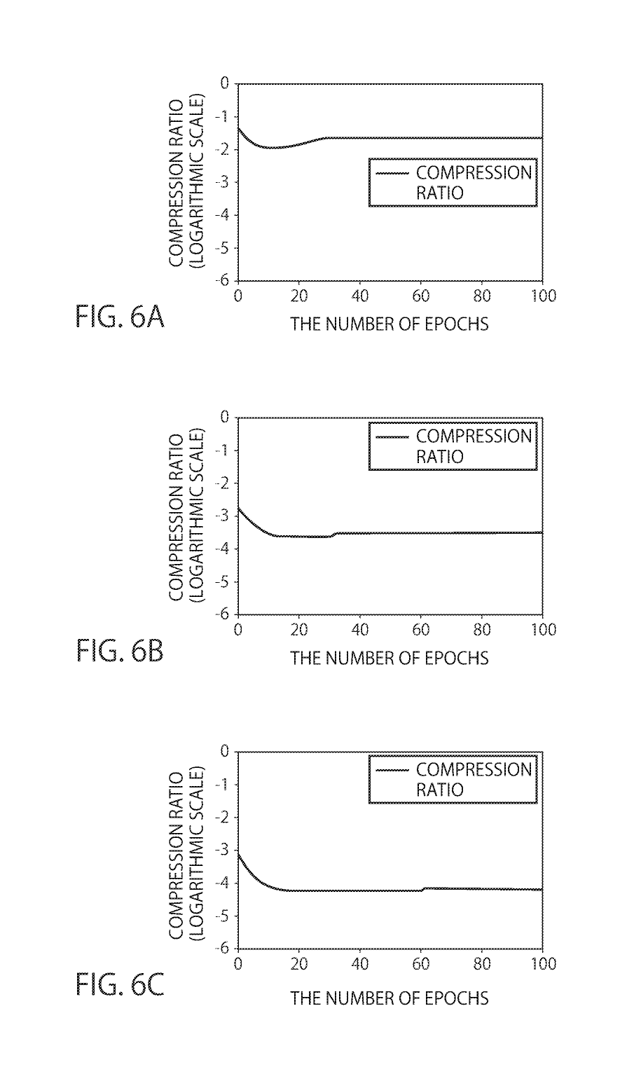

The larger this reference variance scale factor α is, the smaller the number of transmission parameters is, and therefore, a compression ratio becomes low. The ones illustrating states of this compression are graphs illustrated in FIG. 6A to FIG. 6C. They are the graphs corresponding to FIG. 5A to FIG. 5C, and FIG. 6A, FIG. 6B, and FIG. 6C are graphs each illustrating the compression ratio of transmission data in cases of the reference variance scale factor of α=1, the reference variance scale factor of α=2, and the reference variance scale factor of α=3 respectively. In FIG. 6, vertical axes each represent the compression ratio and horizontal axes each represent the number of steps, and the vertical axes each have a logarithmic scale in which 10 is set as a radix.

In reading from the graphs, in the case of the reference variance scale factor of α=1, a data amount of about 1/40, namely, a compression ratio of about 1/40 is obtained as compared with the case of non-compression. Similarly, in the case of the reference variance scale factor of α=2, a compression ratio of about 1/3000 is obtained, and in the case of the reference variance scale factor of α=3, a compression ratio of about 1/20000 is obtained. From these graphs and the graphs in FIG. 5, possible achievement of a low compression ratio and, at the same time, a small decrease in accuracy can be read. That is, in the learning system 1, an improvement in a communication data amount and furthermore a communication speed between the distributed learning apparatuses 10, and a decrease in communication time in a time required for learning, with maintained high accuracy, can be read.

As described above, according to the distributed learning apparatus 10 according to this embodiment, in distributed deep learning, it is possible to suppress a decrease in accuracy while also achieving a low compression ratio of data required to communicate. From the above, when the distributed deep learning is performed, it becomes possible to perform deep learning in which performance of a computer is effectively utilized, without rate-limiting a communication speed.

Note that the gradient compression technique according to this embodiment allows compression of the communication in general, and therefore, asynchronous-type distributed deep learning as well as the synchronous-type distributed deep learning in which a plurality of the distributed learning apparatuses 10 are synchronized with one another at the timing of communication as explained above can be applied thereto. Further, it is possible to operate on not only a GPU cluster but also a cluster using another accelerator, and for example, also in a case of leading to such rate-limiting of a communication speed as a connection of a plurality of dedicated chips of a FPGA (Field-Programmable Gate Array) or the like, namely, a mutual connection of accelerators, the application thereof is possible.

The gradient compression according to this embodiment is independent of an attribute of data, and therefore, it can be used for learning by various neural nets for image processing, for text processing, for voice processing, or the like. Furthermore, a focus on a relative size of the gradient makes an adjustment of the hyperparameter easy. As a degree of compression, since the statistic being the first-order moment and the statistic being the second-order moment are compared, a modified example in which moments of other dimensions are compared with each other also falls within a range of equivalents of this embodiment. Further, performing the quantization by the exponent and compressing data make it possible to deal with a scale having a wider value.

In the above-described entire description, at least a part of the distributed learning apparatus 10 may be configured by hardware, or may be configured by software and a CPU and the like perform the operation based on information processing of the software. When it is configured by the software, a program which achieves the distributed learning apparatus 10 and at least a partial function thereof may be stored in a storage medium such as a flexible disk or a CD-ROM, and executed by making a computer read it. The storage medium is not limited to a detachable one such as a magnetic disk or an optical disk, but it may be a fixed-type storage medium such as a hard disk device or a memory. That is, the information processing by the software may be concretely implemented by using a hardware resource. Furthermore, the processing by the software may be implemented by the circuit of a FPGA or the like and executed by the hardware. The generation of a learning model or processing after an input in the learning model may be performed by using, for example, an accelerator such as a GPU. Processing by the hardware and the software may be implemented by one or a plurality of processing circuitries representing CPU, GPU, and so on and executed by this processing circuitry. That is, the gradient compressing apparatus according to this embodiment may include a memory which stores necessary information of data, a program, and the like, a processing circuitry which executes a part or all of the above-described processing, and an interface for communicating with the exterior.

Further, a gradient compression model according to this embodiment can be used as program modules being a part of artificial-intelligence software. That is, based on a model in which a CPU of a computer is stored in storage, it performs an operation, and operates so as to output results.

A person skilled in the art may come up with addition, effects or various kinds of modifications of the present invention based on the above-described entire description, but, examples of the present invention are not limited to the above-described individual embodiments. Various kinds of addition, changes and partial deletion can be made within a range that does not depart from the conceptual idea and the gist of the present invention derived from the contents stipulated in claims and equivalents thereof.

For example, as illustrated in FIG. 1, the distributed learning apparatus 10 according to this embodiment may be mounted by one computer of a plurality of computers included in the learning system 1. As illustrated in FIG. 2, it is sufficient that gradients of parameters calculated by the learner 108 are compressed and an output to the transmit buffer 104 is made so as to allow the communicator 100 to perform transmission. Further, it is possible to be such an apparatus as can perform distributed learning by mounting the gradient compressing apparatus 20 on a computer different from that of the learner 108 and by the gradient compressing apparatus 20, the learner 108, the communicator 100, and so on collaborating with one another. In the learning system 1, finally, learning is distributed by a plurality of the distributed learning apparatuses 10 connected via a plurality of communication paths, to execute a piece of learning. Note that there is no need to be a plurality of computers, but the learning system 1 may be, for example, a system in which a plurality of accelerators are included in the same computer and the plurality of accelerators perform distributed learning while communicating with one another via a bus.

1. A gradient compressing apparatus comprising:
a memory that stores data; and
processing circuitry coupled to the memory and configured to:
calculate statistics of gradients for a plurality of parameters being learning targets with respect to an error function in learning;
determine, based on the statistics, whether or not a parameter of the plurality of parameters is a transmission parameter that transmits gradients regarding each of the parameters via a communication network; and
quantize a gradient representative value being a representative value of gradients for the transmission parameter.

2. The gradient compressing apparatus according to claim 1,
wherein the processing circuitry calculates the statistics based on a mean value and a variance value of gradients.

3. The gradient compressing apparatus according to claim 2,
wherein the processing circuitry determines that the parameter is the transmission parameter when a value of a square of a mean value of gradients of the parameter is larger than a value obtained by multiplying a variance value of gradients of the parameter or a mean value of squares of gradients of the parameter by a reference variance scale factor being a predetermined scale factor.

4. The gradient compressing apparatus according to claim 1,
wherein the processing circuitry quantizes the gradient representative value to be a predetermined quantifying bit number.

5. The gradient compressing apparatus according to claim 2,
wherein the processing circuitry quantizes the gradient representative value to be a predetermined quantifying bit number.

6. The gradient compressing apparatus according to claim 3,
wherein the processing circuitry quantizes the gradient representative value to be a predetermined quantifying bit number.

7. The gradient compressing apparatus according to claim 4,
wherein the processing circuitry quantizes the gradients to be the predetermined quantifying bit number, based on an exponent value of the gradient representative value.

8. The gradient compressing apparatus according to claim 6,
wherein the processing circuitry quantizes the gradients to be the predetermined quantifying bit number, based on an exponent value of the gradient representative value.

9. The gradient compressing apparatus according to claim 1,
wherein the processing circuitry outputs the quantized gradient representative value of the parameter.

10. The gradient compressing apparatus according to claim 4,
wherein the processing circuitry outputs the quantized gradient representative value of the parameter.

11. The gradient compressing apparatus according to claim 6,
wherein the processing circuitry outputs the quantized gradient representative value of the parameter.

12. The gradient compressing apparatus according to claim 7,
wherein the processing circuitry outputs the quantized gradient representative value of the parameter.

13. The gradient compressing apparatus according to claim 8,
wherein the processing circuitry outputs the quantized gradient representative value of the parameter.

14. The gradient compressing apparatus according to claim 9,
wherein the processing circuitry, when a value obtained by quantizing the gradient representative value is smaller than a predetermined value, does not output the transmission parameter corresponding to the gradients.

15. The gradient compressing apparatus according to claim 10,
wherein the processing circuitry, when a value obtained by quantizing the gradient representative value is smaller than a predetermined value, does not output the transmission parameter corresponding to the gradients.

16. The gradient compressing apparatus according to claim 11,
wherein the processing circuitry, when a value obtained by quantizing the gradient representative value is smaller than a predetermined value, does not output the transmission parameter corresponding to the gradients.

17. The gradient compressing apparatus according to claim 12,
wherein the processing circuitry, when a value obtained by quantizing the gradient representative value is smaller than a predetermined value, does not output the transmission parameter corresponding to the gradients.

18. The gradient compressing apparatus according to claim 13,
wherein the processing circuitry, when a value obtained by quantizing the gradient representative value is smaller than a predetermined value, does not output the transmission parameter corresponding to the gradients.

19. A computer-implemented gradient compressing method comprising:
calculating, in a hardware processor of a computer, statistics of gradients calculated for a plurality of parameters being learning targets with respect to an error function in learning;
determining, based on the statistics, whether or not a parameter of the plurality of parameters is a transmission parameter that transmits gradients regarding each of the parameters via a communication network; and
quantizing a gradient representative value being a representative value of gradients for the transmission parameter.

20. A non-transitory computer readable medium storing a program which, when executed by a processor of a computer performs a method comprising:
calculating statistics of gradients calculated for a plurality of parameters being learning targets with respect to an error function in learning;
determining, based on the statistics, whether or not a parameter of the plurality of parameters is a transmission parameter that transmits gradients regarding each of the parameters via a communication network; and
quantizing a gradient representative value being a representative value of gradients for the transmission parameter.
